(19) United States
(12) Patent Application Publication
(10) Pub. No.: US 2007/0200136 A1
(43) Pub. Date: Aug. 30, 2007

(54) Isolated zener diodes

(76) Inventors: Ronghua Zhu, Chandler, AZ (US); Vishnu K. Khemka, Phoenix, AZ (US); Amitava Bose, Tempe, AZ (US); Todd Roggenbauer, Chandler, AZ (US)

Correspondence Address: INGRASSIA FISHER & LORENZ, P.C. (FS), 7150 E. CAMELBACK ROAD, SUITE 325, SCOTTSDALE, AZ, 85251, US

(21) Appl. No.: 11/364,769

(22) Filed: Feb. 28, 2006

(51) Int. Cl. H01L 29/00

(52) U.S. Cl. 257/106

(57) ABSTRACT

The present disclosure relates to isolated Zener diodes (100) that are substantially free of substrate current injection when forward biased. In particular, the Zener diodes (100) include an “isolation tub” structure that includes surrounding walls (150, 195) and a base (130) formed of semiconductor regions. In addition, the diodes (100) include silicide block (260) extending between anode (210) and cathode (220) regions. The reduction or elimination of substrate current injection overcomes a significant shortcoming of conventional Zener diodes that generally all suffer from substrate current injection when they are forward biased. Due to this substrate current injection, the current from each of a conventional diode's two terminals is not the same.

### TECHNICAL FIELD

The present invention relates generally to semiconductors and more particularly to isolated Zener diodes and methods of making the same.

### BACKGROUND

Zener diodes are some of the most extensively-used components in semiconductor technology, being used for a wide variety of applications, including voltage regulation and protection from electrostatic discharge events. Two different kinds of breakdown current may affect the operation of a diode at breakdown: impact ionization, or avalanche breakdown current; and tunneling, or Zener breakdown current. The term “Zener diode,” as it is classically used, and as it will be used herein, refers to a diode in which tunneling breakdown and avalanche breakdown occur simultaneously.

In power integrated circuit (IC) technology, the Zener diode is commonly integrated into a circuit and is in “discrete” form as a separate unit as is normally the case. In general, Zener diodes, especially when used in smart power technologies, should have both zero temperature coefficient (“zero TC”) and long term stability. Zero temperature coefficient means that the reverse voltage is substantially invariant with temperature, within a useful temperature range. Long term stability means that the reverse voltage does not change with time over the useful life of the device. Due to Zener diode's zero TC and long term stability, they are widely used in voltage clamping and reference. However, conventional Zener diodes suffer from substrate current injection when forward biased. This substrate current injection may result in design difficulty since the diode's two terminal currents are not the same. The injected current may also disturb operation of other parts of the circuit.

Accordingly, it is desirable to develop a Zener diode that retains characteristics of zero TC and long term stability, and that also has reduced substrate current when forward biased. In addition, it is desirable that the Zener diode not disturb operation of other components of the circuit with which it is integrated. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

A more complete understanding of the present disclosure may be derived by referring to the detailed description and claims when considered in conjunction with the following figures. For simplicity and clarity of illustration, the drawing figures illustrate the general manner of construction, and descriptions and details of well-known features and techniques may be omitted to avoid unnecessarily obscuring the described technology. Additionally, elements in the drawing figures are not necessarily drawn to scale. For example, the dimensions of some of the elements in the figures may be exaggerated relative to other elements to help improve understanding of embodiments of the present invention. The same reference numerals in different figures may denote the same elements.

FIG. 1 is schematic top view of an isolated Zener diode according to an embodiment of the present disclosure, not depicting certain oxide surface regions to allow showing more underlying detail;

FIG. 2 is a schematic cross sectional view of one half of the Zener diode of FIG. 1;

FIG. 3 is a graph showing the reduced substrate injection current of an embodiment of the Zener diode of the present disclosure as compared to prior Zener diodes; and

FIG. 4 is a flow chart of an embodiment of a process for making the Zener diode of the present disclosure.

### DETAILED DESCRIPTION

The following detailed description is merely illustrative in nature and is not intended to limit the scope of the claims and uses of the devices herein disclosed. Furthermore, there is no intention to be bound by any expressed or implied theory presented in the preceding technical field, background or the following detailed description.

As a preliminary matter, the terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. In addition, a first semiconductor region having a first conductivity may, for example, have the same conductivity as a second semiconductor region having a second conductivity. Thus while regions may be distinct by numbering as “first” and “second”, associated properties may not be distinct. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

Further, the terms “left,” “right,” “front,” “back,” “top,” “bottom,” “over,” “under,” in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

In addition, the terms “inboard” and “outboard” as used herein, relate to position relative to a central axis of symmetry or other point, line or plane of reference. Thus, “inboard” means closer to the reference than another component; and “outboard” means further from the reference than another component. Unless otherwise indicated, the frame of reference in this disclosure is a center line or plane of symmetry.

The present disclosure relates to isolated Zener diodes that are substantially free of substrate current injection when forward biased. While the isolated Zener diodes provide near zero substrate injection currents, the magnitude of any injection current depends upon other factors as well, such as for example any potential applied to the isolation. In general, the term “substantially free of substrate injection current” means that the isolated Zener diodes have an injection current, when forward biased, of less than about 8%, and more especially less than about 3%, of the total anode current when cathode, body and isolation are at the same potential; and, when a 5 volt potential is applied to the isolation, the injection current reduces further to less than about 1% and more especially less than about 0.3% of total anode current. These isolated Zener diodes will consequently find many uses, especially in advanced smart power technologies.

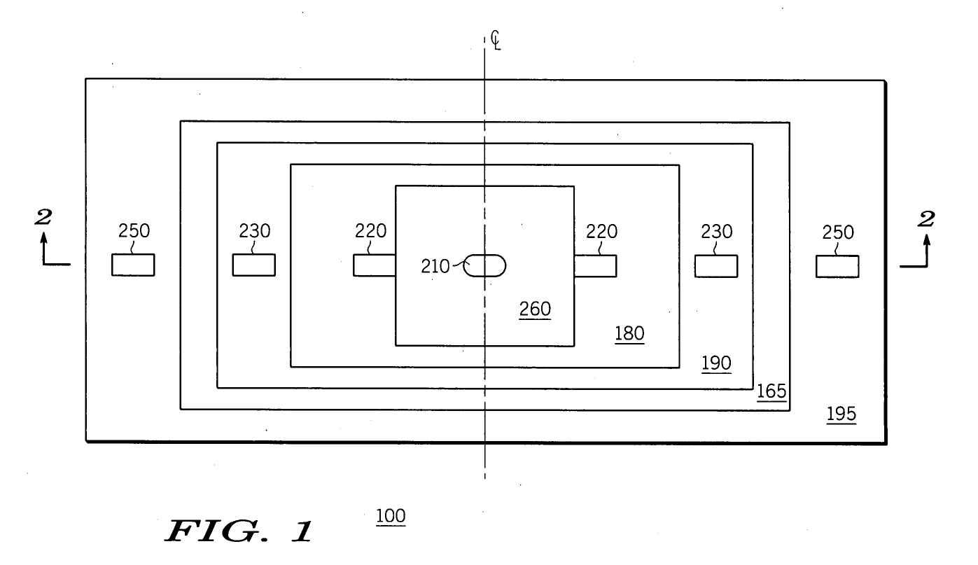

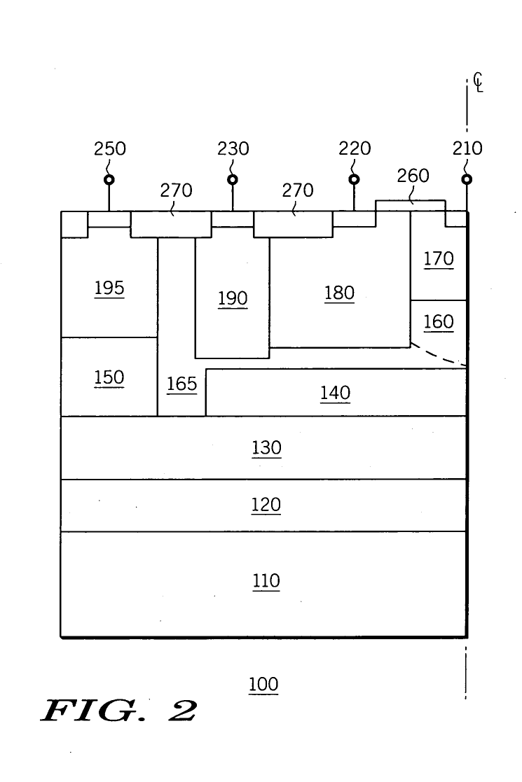

FIGS. 1 and 2 represent a top view and half of a cross sectional view of an embodiment of one of the isolated Zener diodes of the present disclosure. FIG. 1 depicts a symmetrical diode, but symmetry is not necessary according to the present disclosure. In order to show more detail, oxide regions 270 shown in FIG. 2 are not shown in FIG. 1 since these would overlie and obscure details of other semiconductor regions.

In FIG. 1, the isolated Zener diode 100 has a central anode 210, surrounded by silicide block 260 that extends to the cathode 220. Silicide block 260 overlies a region 170, not shown in FIG. 1, but shown in FIG. 2. The anode 210 is formed within region 170, as seen more clearly in FIG. 2. Region 170 is surrounded by region 180, in which cathodes 220 are formed. Region 180 is surrounded by region 190 in which bodies 230 are formed. Region 190 is surrounded by region 165 which is surrounded by region 195. Isolation 250 are formed in region 195. Region 195 may be surrounded by deep trenches, not shown.

Referring now to FIG. 2, the diode 100 is overlaid onto a substrate 110. Layer 110 may be for example a heavily doped p-type substrate. Layer 110 is overlaid with optional layer 120, which is for example an optional Pepi-1 epitaxial layer. Layer 120, if present, is in turn overlaid with layer 130, for example a highly doped n-type buried layer. If layer 120 is not present, layer 130 is formed onto layer 110. At least a portion of the central region of layer 130 is overlaid with layer 140, which may be a P-extension layer. As can be seen, layer 140 is interposed between the cathode 220 and layer 130. The portion of the layer 130 not overlaid with layer 140, is overlaid with a region 150, which may be a heavily doped n-type sinker such as an n-type link region.

In the central region of diode 100 (i.e. the right side of FIG. 2), the regions extending between layer 140 and the anode 210 are as follows. In this embodiment, an optional P-type region 160 overlies layer 140. This region is not essential, and may be omitted in favor of extending region 165 into this area. Region 165 may be for example a p-type epitaxial region. A region 170, that may be a moderately doped n-type well, has an anode 210 formed in its upper surface. Region 170 is located above and in contact with region 160, if such is present, or otherwise is in contact with region 165.

The diode structure extending from layer 130 to cathode 220 includes the following regions. The region above layer 140 [may be 160 (if present) or 165 (if region 160 is not present)], includes a region 180. Region 180 may be a heavily doped n-type well. A cathode 220 is formed in the upper surface region of region 180. As shown, peripheral areas of region 180 interface with peripheral areas of region 170 and also peripheral areas of region 160, underlying the anode 210.

In FIG. 2 the area underlying the body 230 includes a region 190, for example a moderately doped p-type well, which is depicted as spaced from region 140 at peripheral regions. The body 230 is formed in the upper surface of region 190.

Referring to the left side of FIG. 2, a region 150, which may be of the same composition as region 130 or may be highly doped n-type sinker, extends from above region 130. A region 195 extends from peripheral contact with region 165 to the upper surface of the diode 100. Region 195 may be for example a moderately doped n-type well. Isolation 250 is formed in the upper surface of region 195.

A silicide block or layer 260 extends between cathode 220 and anode 210 on the upper surface of the Zener diode 100. In addition, oxide regions 270 extend between isolation 250 and body 230, and between body 230 and cathode 220. These are not shown in FIG. 1 to permit showing underlying details.

In the embodiment of FIG. 2, the stacked regions 195 and 150 extend around the proximity of the outer perimeter of the diode thereby surrounding the inner regions (as seen in FIG. 1 where upper region 195 is shown). Regions 150 and 195 form vertical sides of a “tub shape”, with region 130 as base of the tub. The tub, referred to as an “isolation tub,” is believed responsible for reduction or elimination of the substrate injection current. We are not bound by this belief and regardless of theory or belief; the benefit of reduced current is obtained in the diodes of this disclosure.

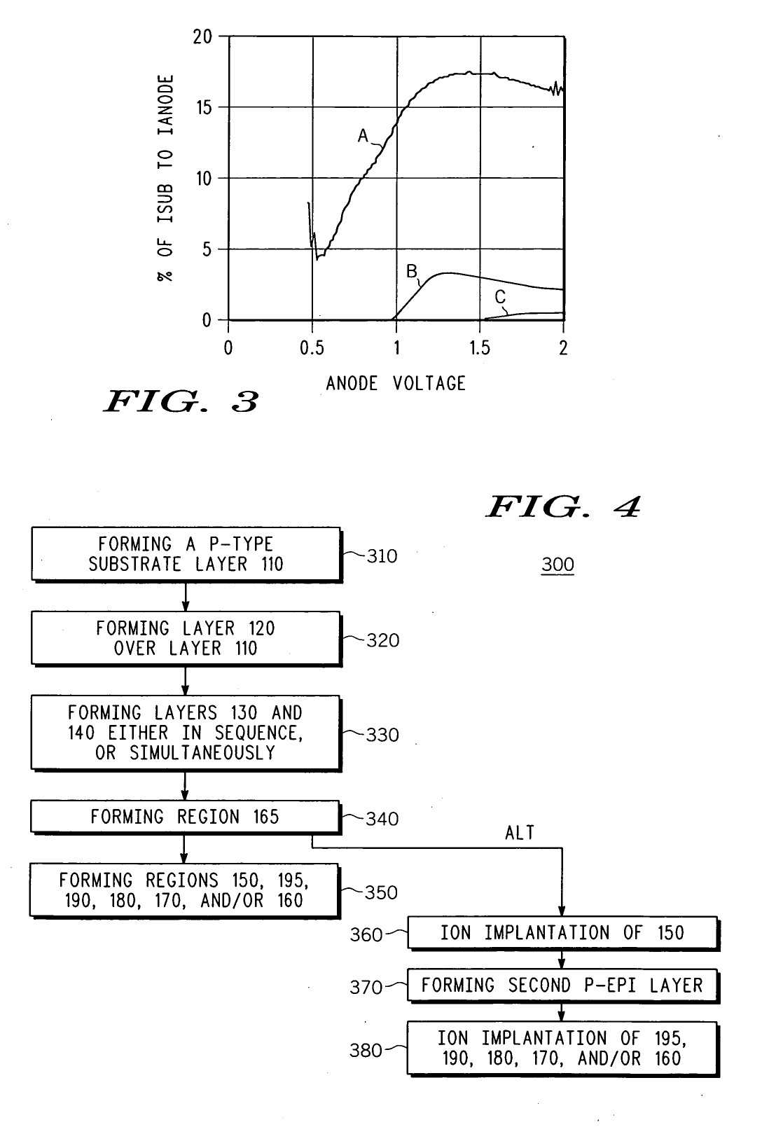

In general, examples of the isolated Zener diodes of this disclosure have substrate injection currents of as little as 0.5% to about 3% of the total anode current when forward biased, as can be seen in the graph of FIG. 3. This figure is explained in more detail below. Typically, the substrate injection currents are reduced by from about 17% to about 3% when the cathode, body and isolation are at the same potential. It reduces to about 0.5% when isolation potential is 5 volts higher than the body.

It will be readily apparent to one of skill in the art who has read this disclosure and reviewed the drawings that there are a variety of ways to make the isolated Zener diodes of the present disclosure. One example will be explained, with the understanding that other methods with modifications and variations within the scope of knowledge of a person of ordinary skill in the art are within the scope of the appended claims.

Referring to FIGS. 2 and 4, where FIG. 4 depicts schematically a method 300 of making an example of an isolated Zener diode, a p-type substrate layer 110 is formed in block 310. An (optional) epitaxial layer (Pepi-1) 120 is formed over layer 110, in block 320. After layer 120 is formed, layers 130 and 140 may be formed either in sequence, or simultaneously, in block 330. Layer 130 may be formed by ion implantation followed by diffusion and annealing, for example. After formation of layer 130 and region 140, region 165 (P-epi) is formed, in block 340. This may be followed by implantation for regions 150, 195, 190, 180, 170 and/or 160 with appropriate N and P types, in block 350. Alternatively, after formation of layer 130 and region 140, region 165 is formed, followed by n-type implantation for region 150, in block 360. Then a second P-epi layer is deposited in block 370 to form the remainder of region 165, followed by implantation of regions 195, 190, 180, 170 and/or 160, in block 380. In the method of making the isolated Zener diode, the forming of the region 195 (and optional region 150, if present) creates surrounding walls of an isolation tub. These walls extend downward to layer 130 that forms the base of the tub.

A Zener diode that includes a first semiconductor region having a first conductivity with an anode formed in the first region. It also has a second semiconductor region having a second conductivity with a cathode formed in the second region. There is also a third semiconductor region, below the first and second regions and spaced apart from the first and second regions. In addition, there is a fourth semiconductor region extending vertically, located outboard of the first and second semiconductor regions. A silicide block extends from the cathode region to the anode region. When the diode is forward biased, it is substantially free of substrate injection current. The third region may be a highly doped n-type buried layer. The fourth semiconductor region may be a moderately doped n-type well. The fourth semiconductor region, which surrounds the first and second regions, may substantially form sides of a tub shape, with the third region as a base of the tub.

In addition, the diode may have a moderate to highly doped p-type fifth region interposed between the first region and the third region, and between the second region and the third region.

The fourth region may include an upper region comprising a moderately doped n-type well, and a lower region comprising a heavily doped n-type sinker region.

The perimeters of the first region and second region may not be in contact with a perimeter of the fifth region.

The diode may further include a sixth region interposed between the first region and the fifth region, and between the second region and the fifth region. The sixth region may be a p-type epitaxial region.

The diode has a substrate injection current of less than about 3.0% of the total anode current when no potential is applied to an isolation, and less than about 0.3% of total anode current when a 5 volt potential is applied to the isolation relative to the body.

In another embodiment, there is presented a Zener diode that includes four regions. A first semiconductor region includes a moderately doped n-type well with an anode formed in the first region. A second semiconductor region includes a highly doped n-type well with a cathode formed in the second region. A third semiconductor region includes a highly doped n-type buried layer. The third region is located below the first and second regions and spaced apart from the first and second regions. A fourth semiconductor region extends vertically, outboard of the first and second semiconductor regions. The fourth semiconductor region surrounds the first and second regions and substantially forms sides of a tub shape, with the third region as a base of the tub. A silicide block extends from the vicinity of the cathode region to the vicinity of the anode region. When the diode is forward biased, it is substantially free of substrate injection current.

When forward biased, substrate injection current may be less than about 3.0% of the total anode current when cathode body and isolation are at the same potential, and less than about 0.3% of total anode current when a 5 volt potential is applied to the isolation relative to he body.

The diode may in addition include a moderate to highly doped p-type fifth region interposed between the first region and the third region, and between the second region and the third region. Further, the diode may include a sixth region interposed between the first region and the fifth region, and between the second region and the fifth region. The sixth region may be a p-type epitaxial region.

The present disclosure also includes a method of making an isolated Zener diode that includes several process steps. The process includes forming a first semiconductor region having a first conductivity; forming a second semiconductor region having a second conductivity; forming an anode in the first region and a cathode in the second region; forming a third semiconductor region, below the first and second regions, the region spaced apart from the first and second regions; and forming a fourth semiconductor region extending vertically, the fourth region outboard of the first and second semiconductor regions so that the fourth region forms walls of a tub and the third region forms a base of the tub. A silicide block is configured to extend from the vicinity of the cathode region to the vicinity of the anode region.

The method may include forming the third semiconductor region to include an n-type buried layer. Further, the method may include forming the fourth semiconductor region to include a moderately doped n-type well. In addition, the method includes the possibility of forming the fourth semiconductor region to include a moderately doped n-type well. Forming the fourth region may include forming and upper region and forming a lower region. The upper region may be a moderately doped n-type well, and the lower region may be a highly doped n-type sinker region.

The following example is intended to illustrate an advantage of an embodiment of the present disclosure and does not limit the scope of the disclosure or the appended claims.

### EXAMPLE

Substrate injection currents were compared for a pair of Zener diodes: a Control Zener diode A and an isolated Zener diode according to the present disclosure.

For the control Zener diode, measurements were taken while the cathode and the substrate were ground while ramping the anode from 0 to 2 volts (curve A). For the isolated Zener diode, the measurement was done by ramping the anode from 0 to 2 volts while keeping other terminals at ground (substrate, body, cathode and isolation terminals). The measured result is shown in FIG. 3, curve B. For curve C, also relating to the isolated Zener diode, the isolation is biased at 5 volts instead of ground.

The results are shown in FIG. 3, a graph of anode voltage (x-axis) versus percentage of substrate injection to total anode voltage (y-axis). The curve A for the Control shows a relatively high percentage of substrate to anode current for voltage, while that for the isolated Zener diode with isolation potential (Vᵢₛₒ) grounded (curve B) has a dramatic reduction in percent substrate current. With Vᵢₛₒ set at five volts, the reduction is even more dramatic and approaches zero.

While at least one example embodiment has been presented in the foregoing detailed description, it should be appreciated that a vast number of variations exist. It should also be appreciated that the example embodiment or embodiments described herein are not intended to limit the scope, applicability, or configuration of the invention in any way. Rather, the foregoing detailed description will provide those skilled in the art with a convenient road map for implementing the described embodiment or embodiments. It should be understood that various changes can be made in the function and arrangement of elements without departing from the scope of the invention as set forth in the appended claims and the legal equivalents thereof.

What is claimed is:

1. A Zener diode comprising:
a first semiconductor region having a first conductivity, an anode formed in the first region;
a second semiconductor region having a second conductivity, a cathode formed in the second region;
a third semiconductor region, below the first and second regions, the region spaced apart from the first and second regions;
a fourth semiconductor region extending vertically outboard of the first and second semiconductor regions; and
a silicide block extending from an anode region to a cathode region;
wherein, when the diode is forward biased, it is substantially free of substrate injection current.

2. The diode of claim 1, wherein the third region comprises a highly doped n-type buried layer.

3. The diode of claim 1, wherein the fourth semiconductor region comprises a moderately doped n-type well.

4. The diode of claim 1, wherein the fourth semiconductor region surrounds the first and second regions and substantially forms sides of a tub shape, with the third region as a base of the tub.

5. The diode of claim 1, further comprising a moderate to highly doped p-type fifth region interposed between the first region and the third region, and between the second region and the third region.

6. The diode of claim 1, wherein the fourth region comprises an upper region comprising a moderately doped n-type well, and a lower region comprising a heavily doped n-type sinker region.

7. The diode of claim 5, wherein perimeters of the first region and second region are not in contact with a perimeter of the fifth region.

8. The diode of claim 7, further comprising a sixth region interposed between the first region and the fifth region, and between the second region and the fifth region.

9. The diode of claim 8, wherein the sixth region is a p-type epitaxial region.

10. The diode of claim 1, wherein the substrate injection current is less than about 3.0% of the total anode current when cathode, body and isolation are at the same potential, and less than about 0.3% of total anode current when a 5 volt potential is applied to a isolation relative to body.

11. A Zener diode comprising:
a first semiconductor region comprising a moderately doped n-type well, an anode formed in the first region;
a second semiconductor region comprising a highly doped n-type well, a cathode formed in the second region;
a third semiconductor region comprising a highly doped n-type buried layer, the third region below the first and second regions and spaced apart from the first and second regions;
a fourth semiconductor region extending vertically outboard of the first and second semiconductor regions, the fourth semiconductor region surrounding the first and second regions and substantially forming sides of a tub shape, with the third region as a base of the tub; and
a silicide block extending from a vicinity of a cathode to a vicinity of an anode;
wherein, when the diode is forward biased, it is substantially free of substrate injection current.

12. The diode of claim 11 wherein, when forward biased the substrate injection current is less than about 3.0% of the total anode current when cathode, body and isolation are at the same potential, and less than about 0.3% of total anode current when a 5 volt potential is applied to isolation relative to body.

13. The diode of claim 11, further comprising a moderate to highly doped p-type fifth region interposed between the first region and the third region, and between the second region and the third region.

14. The diode of claim 13, further comprising further comprising a sixth region interposed between the first region and the fifth region, and between the second region and the fifth region.

15. The diode of claim 14, wherein the sixth region is a p-type epitaxial region.

16. A method of making an isolated Zener of claim 1, comprising:
forming a first semiconductor region having a first conductivity;
forming a second semiconductor region having a second conductivity;
forming an anode in the first region and a cathode in the second region;
forming a third semiconductor region, below the first and second regions, the region spaced apart from the first and second regions;
forming a fourth semiconductor region extending vertically, the fourth region outboard of the first and second semiconductor regions so that the fourth region forms walls of a tub and the third region forms a base of the tub; and
configuring a silicide block to extend from a vicinity of an anode to a vicinity of a cathode.

17. The method of claim 16, wherein the forming the third semiconductor region comprises forming an n-type buried layer.

18. The method of claim 16, wherein forming the fourth semiconductor region comprises forming a moderately doped n-type well.

19. The method of claim 17, wherein forming the fourth semiconductor region comprises forming a moderately doped n-type well.

20. The method of claim 16 wherein the forming of the fourth semiconductor region comprises forming an upper region and forming a lower region, the upper region comprising a moderately doped n-type well, and the lower region comprising a highly doped n-type sinker region.
